(19) United States
(12) Patent Application Publication
(10) Pub. No.: US 2009/0061115 A1
(43) Pub. Date: Mar. 5, 2009

(54) CAPACITIVE TOUCH SCREEN AND MANUFACTURING METHOD THEREOF

(75) Inventors: XIANFANG WANG, SHENZHEN (CN); JIANWEI LIU, SHENZHEN (CN)

Correspondence Address: ROSENBERG, KLEIN & LEE, 3458 ELLICOTT CENTER DRIVE-SUITE 101, ELLICOTT CITY, MD, 21043, US

(73) Assignee: SHENZHEN H&T INTELLIGENT CONTROL CO., LTD., SHENZHEN (CN)

(21) Appl. No.: 12/119,537

(22) Filed: May 13, 2008

(30) Foreign Application Priority Data
Aug. 30, 2007 (CN) 200710076821.3

(51) Int. Cl. C09K 19/02; G03F 7/00

(52) U.S. Cl. 428/1.1; 430/319

(57) ABSTRACT

A capacitive touch screen includes an indium tin oxide layer and a transparent protection layer on top of the indium tin oxide layer, wherein buttons and lines are etched on the indium tin oxide layer, and each of the buttons is connected to an electronic control circuit through at least one of the lines. A method for manufacturing a capacitive touch screen comprises: (A1) providing a first indium tin oxide layer; (A2) etching buttons and lines on the first indium tin oxide layer through photolithography process. The buttons and lines are etched directly on the indium tin oxide layer, and the touch screen is integrated with the LCD, which does not increase any thickness and transmits the information in the line by the simplest way. The capacitive touch screen of the invention has high efficiency, exact orientation, convenient installation, low cost, good appearance, etc.

### FIELD OF THE INVENTION

This invention relates to a touch screen and its manufacturing method. More specifically, the invention relates to a capacitive touch screen and a method for manufacturing the same.

### BACKGROUND OF THE INVENTION

The capacitive touch screen works according to the fact that the induced current of human body can change the resistivity of the capacitive touch screen. The ITO (Indium tin oxide or tin-doped indium oxide) has two main parameters: resistivity and light transmission rate. Generally, the resistivity of the ITO is about 0.0005, and the maximum may reach 0.00005 which is close to the resistivity of metal. The light transmission rate of the ITO exceeds 90%. The resistance of the ITO conductive glass is normally in a range of 500-650 ohm, which is qualified for use in the capacitive touch screen. The capacitive touch screen includes a silica glass protect layer used as the outer layer and an interlayer of ITO coating. Four corners of the capacitive touch screen extend with four electrodes. When the capacitance touch screen field (its reference state) is altered by the user's finger, electronic circuits located at each corner of the panel measure the resultant ‘distortion’ in the sine wave characteristics of the reference field and send the information about the event to the controller for mathematical processing. When a finger touches the screen and draws a minute amount of current to the contact point, creating a voltage drop. The current flow from each corner is proportional to the distance to the touch point. The location of the contact point is calculated by the controller according to the ratio of the four current flows. However, this calculation method is of high complexity, high cost, low efficiency and high error rate.

Moreover, for the known product consisting of the LCD and the touch screen, the LCD is normally provided on top of the touch screen, and the thickness of this structure is large and attachments should be needed for connecting the LCD with the touch screen.

### SUMMARY OF THE INVENTION

It is an objective of this invention to provide a capacitive touch screen which solves above-mentioned shortcomings.

To achieve the above objective, the present invention provides a capacitive touch screen includes an indium tin oxide layer and a transparent protect layer on top of the indium tin oxide layer. Buttons is etched on the indium tin oxide layer, and each of the buttons is connected to an electronic control circuit by at least one etched line.

Preferably, the line is connected to the electronic control circuit by pin, FPC (flexible printed circuit) or zebra barcode.

Preferably, a liquid crystal screen is provided below the indium tin oxide layer, and the liquid crystal screen is provided with a liquid crystal backlight.

Preferably, a LED indicator light, a VFD (vacuum fluorescent display) and a display screen of organic electroluminescence are provided below the button and the line.

Preferably, the buttons are provided on an upper glass layer; a second indium tin oxide layer is provided below the bottom surface of the upper glass layer; a lower glass layer is provided with a third indium tin oxide layer on the top surface; liquid crystal is filled between the second indium tin oxide layer and the third indium tin oxide layer; a tn-lcd (Twisted Nematic-LCD) is formed by the second indium tin oxide layer, the liquid crystal and the third indium tin oxide layer; the figure of the liquid crystal screen and transmission lines are etched on the second indium tin oxide layer and the third indium tin oxide layer.

Preferably, the line of the button extends from the upper glass layer.

Preferably, the pin of the liquid crystal screen extends from the lower glass layer.

It is another objective of the present invention to provide a method for manufacturing a capacitive touch screen, the method comprising:

(A1) providing a first indium tin oxide layer;

(A2) etching buttons and lines on the first indium tin oxide layer through photolithography process.

Preferably, the first indium tin oxide layer is provided on the top surface of an upper glass layer, and the method further comprises the following steps after step A1:

(B1) providing a second indium tin oxide layer on the bottom surface of the upper glass layer;

(B2) providing a third indium tin oxide layer on the top surface of a lower glass layer;

and after step A2, the method further comprises:

(C1) etching electrodes and lines on the second indium tin oxide layer and the third indium tin oxide layer through photolithography process;

(C2) forming an empty box by using the upper glass layer and the lower glass layer;

(C3) pouring pre-brewage liquid crystal into the empty box, and sealing the box.

Preferably, in the step A1, the first indium tin oxide layer is provided on the bottom surface of a transparent glass layer through sputtering process.

Alternatively, in the step A1, the first indium tin oxide layer is provided on the top surface of the transparent glass layer through sputtering process, and a transparent protection layer is further provided above the first indium tin oxide layer.

The capacitive touch screen of the present invention provides the following advantages: the buttons and lines are etched directly on the indium tin oxide layer, and the touch screen is integrated with the LCD, which does not increase any thickness and transmits the information in the line by the simplest way. The capacitive touch screen of the invention has high efficiency, exact orientation, convenient installation, low cost, good appearance, etc.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings which are schematic and not to scale, wherein:

FIG. 1 is a schematic drawing according to the first embodiment of the capacitive touch screen of the present invention.

FIG. 2 is a schematic structural view of the capacitive touch screen shown in the FIG. 1.

FIG. 3 is a schematic drawing according to the second embodiment of the capacitive touch screen of the present invention.

FIG. 4 is a schematic structural view of the capacitive touch screen shown in the FIG. 3.

FIG. 5 is a schematic drawing according to the third embodiment of the capacitive touch screen of the present invention.

### DESCRIPTION OF THE PREFERRED EMBODIMENT

In the preferred embodiments of the capacitive touch screen, buttons and the lines are formed on the ITO conductive glass by means of exposure etching process. The FPC, the pin, the zebra barcode or other suitable ways may be used for leading out the touch screen.

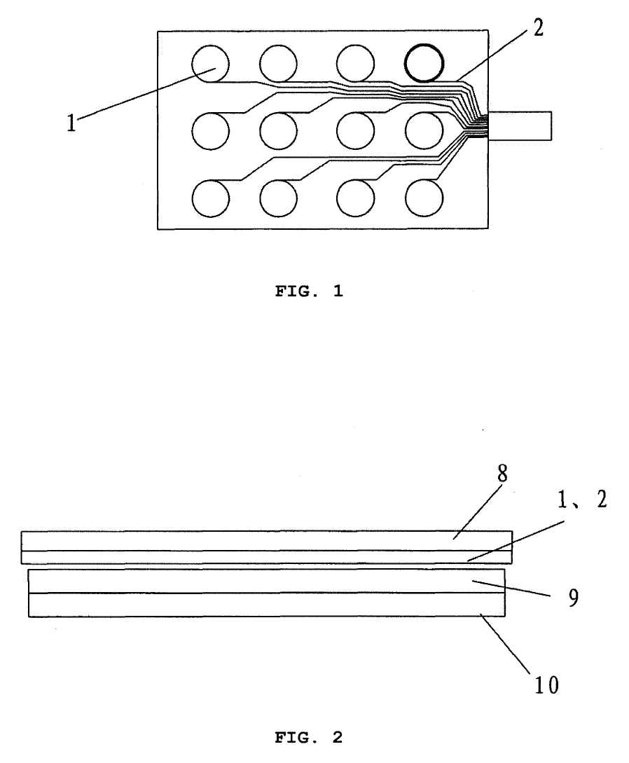

FIGS. 1 and 2 show a structure of the first embodiment of the capacitive touch screen of the present invention. The capacitive touch screen includes the indium tin oxide layer and the transparent protect layer 8 on top of the indium tin oxide layer. The buttons 1 are etched on the indium tin oxide layer. Each of the buttons 1 is connection to the electronic control circuit through at least one line 2. The line 2 may be leaded out by pin or zebra barcode, etc. The liquid crystal screen is disposed below the button 1 and the line 2, and above the liquid crystal backlight 10. According to different requirements, the button 1 and the line 2 can be disposed upon the LED indicator light, VFD (Vacuum Fluorescent Display) and display screen of organic electroluminescence, etc.

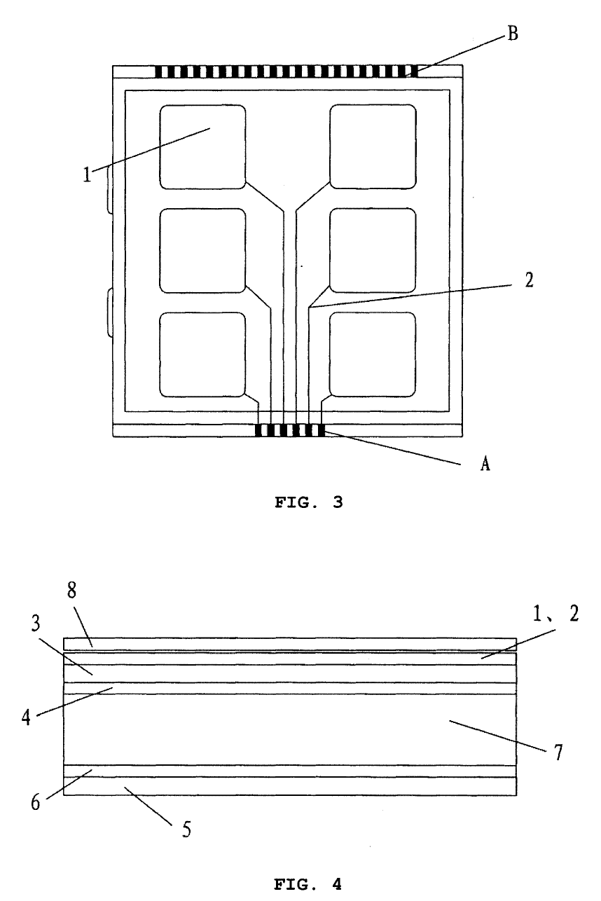

FIGS. 3 and 4 show a structure of the second embodiment of the capacitive touch screen of the present invention. The capacitive touch screen of this embodiment includes a upper glass layer 3 and a lower glass layer 5. The buttons 1 are provided on the top surface of the upper glass layer 3, the second indium tin oxide layer 4 is provided below the bottom surface of the upper glass layer 3, the lower glass layer 5 is provided with a third indium tin oxide layer 6 on the top surface, and liquid crystal 7 is filled between the second indium tin oxide layer 4 and the third indium tin oxide layer 6. The tn-lcd (Twisted Nematic-LCD) is formed by the second indium tin oxide layer 4, the liquid crystal 7 and the third indium tin oxide layer 6. The lines of the buttons 1 are leaded from the upper glass layer 3, as shown by the indicator B in FIG. 3. The pins of the liquid crystal screen are leaded from the lower glass layer 5, as shown by the indicator A in FIG. 3. This structure allows the display and the button to be in the same plane without any holes, any attachments or increasing in sizes.

A method for manufacturing the capacitive touch screen of the first embodiment comprises:

(S1) the first indium tin oxide layer is provided on the top surface of the upper glass layer;

(S2) buttons and lines are etched on the first indium tin oxide layer through photolithography process;

(S3) the FPC, the pin, the zebra barcode or any suitable ways may be used for leading out the touch screen;

(S4) the upper glass layer is provided with the liquid crystal screen, and the liquid crystal screen is provided above the liquid crystal backlight. According to different requirements, the buttons 1 and the lines 2 can be disposed upon the LED indicator light, VFD (Vacuum Fluorescent Display) and display screen of organic electroluminescence, etc.

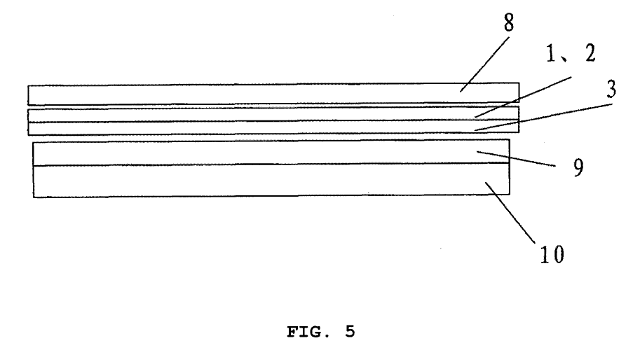

The indium tin oxide layer is provided on the top surface of the transparent glass layer by means of sputtering process. As shown in FIG. 5, the indium tin oxide layer is provided on the top surface of the first glass 3, and the transparent protection layer 8 is provided on the surface of the indium tin oxide layer that is etched with the buttons 1 and lines 2. Alternatively, as shown in FIG. 2, the surface of the indium tin oxide layer that is etched with the buttons 1 and lines 2 is disposed downwards, and the glass layer on the buttons 1 and lines is the transparent protect layer 8, and no additional transparent protect layer is required. A method for manufacturing the capacitive touch screen of the second embodiment comprises:

(S1) the first indium tin oxide layer is provided on the top surface of the upper glass layer;

(S2) the second indium tin oxide layer is provided on the bottom surface of the upper glass layer;

(S3) the third indium tin oxide layer is provided on the top surface of the lower glass layer;

(S4) buttons and lines are etched on the first indium tin oxide layer through photolithography process;

(S5) electrodes and lines are etched on the second indium tin oxide layer and the third indium tin oxide layer through photolithography process;

(S6) an empty box is formed by the upper glass layer and the lower glass layer;

(S7) pre-brewage liquid crystal is poured into the empty box, and then seals the box.

Thus, the touch screen and the LCD are integrated together.

Furthermore, the sequence of the steps S3, S4, S5 is adjustable.

The indium tin oxide layer is provided on the surface of the transparent glass layer by means of sputtering process. Alternatively, both sides of the transparent glass layer may have an indium tin oxide layer in this embodiment.

Based on the technical know-how in the art, the present invention can also be achieved through other methods that do not deviate from its tent or essential features. Therefore, the implementation plans described above are merely illustrative examples and are not in any limited sense. All alterations that fall within the scope of this invention of a scope equivalent to that of this invention are covered by this invention.

What is claimed is:

1. A capacitive touch screen comprising:
an indium tin oxide layer;
a transparent protect layer on top of the indium tin oxide layer;
wherein buttons and lines are etched on the indium tin oxide layer, and each of the buttons is connected to an electronic control circuit by at least one of the lines.

2. The capacitive touch screen according to claim 1, wherein said lines are connected to the electronic control circuit by pin, FPC or zebra barcode.

3. The capacitive touch screen according to claim 1, wherein a liquid crystal screen is provided below said indium tin oxide layer, and the liquid crystal screen is mounted above a liquid crystal backlight.

4. The capacitive touch screen according to claim 1, wherein LED indicator lights, VFDs or display screens of organic electroluminescence are provided below said buttons and said lines.

5. The capacitive touch screen according to claim 1, wherein the buttons are provided on an upper glass layer; a second indium tin oxide layer is provided below the bottom surface of the upper glass layer; a lower glass layer is provided with a third indium tin oxide layer on the top surface; liquid crystal is filled between the second indium tin oxide layer and the third indium tin oxide layer; a tn-lcd is formed by the second indium tin oxide layer, the liquid crystal and the third indium tin oxide layer; the figure of the liquid crystal screen and transmission lines are etched on the second indium tin oxide layer and the third indium tin oxide layer.

6. The capacitive touch screen according to claim 1, wherein the lines of said buttons are leaded from the upper glass layer, and the pins of said liquid crystal screen are leaded from the lower glass layer.

7. A method for manufacturing a capacitive touch screen, comprising:
(A1) providing a first indium tin oxide layer;
(A2) etching buttons and lines on the first indium tin oxide layer through photolithography process.

8. The method of claim 7, wherein said first indium tin oxide layer is provided on the top surface of the upper glass layer, and the method further comprises the following steps after step A1:
(B1) providing a second indium tin oxide layer on the bottom surface of the upper glass layer;
(B2) providing a third indium tin oxide layer on the top surface of a lower glass layer;
and after step A2, the method further comprises:
(C1) etching electrodes and lines on the second indium tin oxide layer and the third indium tin oxide layer through photolithography process;
(C2) forming an empty box by using the upper glass layer and the lower glass layer;
(C3) pouring pre-brewage liquid crystal into the empty box, and sealing the box.

9. The method of claim 7, wherein in the step A1, the first indium tin oxide layer is provided on the bottom surface of a transparent glass layer.

10. The method of claim 7, wherein in the step A1, the first indium tin oxide layer is provided on the top surface of a transparent glass layer, and a transparent protection layer is further provided above the first indium tin oxide layer.
